(19) United States
(12) Patent Application Publication
(10) Pub. No.: US 2003/0100162 A1
(43) Pub. Date: May 29, 2003

(54) Method for forming capacitor of semiconductor device

(76) Inventor: Kwang-Chul Joo, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/285,587

(22) Filed: Nov. 1, 2002

(30) Foreign Application Priority Data
Nov. 28, 2001 (KR) 2001-0074531

(51) Int. Cl. H01L 21/20; H01L 21/8242

(52) U.S. Cl. 438/396; 438/398; 438/240

(57) ABSTRACT

The present invention is related to a method for forming a capacitor of a semiconductor device capable of obtaining an excellent electronic property corresponding to a high degree of integration by forming a Ta₃N₅ thin film having a greater dielectric constant than Ta₂O₅ and TaON thin films through an atomic layer deposition (ALD). Particularly, the Ta₃N₅ thin film is a dielectric layer of the capacitor. The inventive method, including the steps of: forming a bottom electrode coupled to an active area of a semiconductor substrate; performing an atomic layer deposition (ALD) technique to form a Ta₃N₅ dielectric layer with use of a gas precursor of TaCl₅ on the bottom electrode; and forming a top electrode on the Ta₃N₅ dielectric layer.

### FIELD OF INVENTION

The present invention relates to a method for fabricating a semiconductor device, and more particularly, to a method for forming a capacitor of a semiconductor device by providing a Ta₃N₅ thin film for a dielectric layer with use of an atomic layer deposition (ALD) technique so as to obtain a high level of electronic property of the capacitor corresponding to a higher degree of integration.

### DESCRIPTION OF RELATED ART

Integration of a device has been accelerated due to highly developed semiconductor processing skills into microscopic levels. This rapid development of the integration skills results in various researches and studies for reducing a cell area and obtaining a low voltage of an operational voltage. However, despite of this decreased cell areas, a capacitor capacitance for operating a memory device is required greater than 25 fF in order to prevent occurrence of soft error and shortening of a refresh time. Accordingly, a dielectric layer is formed with a NO film, which is stacked with nitride and oxide films, instead of depositing a silicon oxide film. In case of a dynamic random access memory (DRAM) device that uses the NO dielectric film, a storage electrode is formed with a structure of hemi-spherical cylinder as a bottom electrode, and a capacitor height is also increased in order to have a sufficient capacitance.

However, as the height of the capacitor increases, the height difference between a cell area and a peripheral circuit area becomes larger, resulting in a problem of an insufficient margin for depth of focus (DOF) at a later photo exposure process, and this problem has a negative effect on an integration process after a wiring process. Therefore, even a capacitor that uses the NO dielectric film has a limitation to obtain a sufficient capacity required for a next generation DRAM device greater than 256 mega bites.

As a result, there has been actively developed a future generation Ta₂O₅ dielectric film of which dielectric constant ranges from 25 to 30. However, since the Ta₂O₅ film also has an unstable stoichiometry, there exists a Ta substitutional vacancy atom within the thin film due to a compositional ratio difference in between Ta and O. A TaON thin film formation has been suggested to solve this problem by inducing a surface chemical reaction on a wafer with use of evaporation gases such as NH₃ and Ta(OC₂H₅)₅. The TaON thin film formed by the above mentioned method becomes much stable compared to Ta₂O₅ film because of a mutual covalent bond formed as in Ta—O—N with a higher bonding force.

On the other hand, a chemical vapor deposition (CVD) process is employed to form TaON and Ta₂O₅ thin films. As illustrated in FIG. 1A, this deposition using CVD, a source gas (S), a purge gas (P) and a reactant gas (R) are injected during one cycle (C1). Then, as referred in FIG. 1B, precursor gases are absorbed on a surface of a substrate, and the absorbed precursor gases generate surface reaction (c) through surfacial diffusions (B) so as to form a film. However, the above procedures result in unstable compositions and structures in stoichiometry. Especially, an organic substance, Ta(OC₂H₅)₅ used for forming the TaON and Ta₂O₅ thin films, leaves carbon residues, increasing leakage current and deteriorating dielectric breakdown voltage of the dielectric layer.

Meanwhile, in order to obtain a sufficient capacity of a capacitor required for a device operation, a dielectric layer should have uniform thickness over a whole cell, i.e., effective dielectric film thickness (hereinafter, referred as Teff). However, with the continuous growth method adapted the CVD, it is not easy to get a good step coverage over a deep field of a capacitor that has a three dimensional structure. Also, it becomes much difficult to get the good step coverage when a hemi spherical grain (HSG) is applied. That is, the conventional CVD operation has difficulties in obtaining an electronic property of a capacitor and Teff.

### SUMMARY OF THE INVENTION

It is, therefore, an object of the present invention to provide a method for forming a capacitor of a semiconductor device by providing a Ta₃N₅ thin film with the atomic layer deposition (ALD) technique so as to obtain a high level of electronic property of the capacitor corresponding to a high degree of integration of the capacitor.

In accordance with one aspect of the present invention, there is provided a method for fabricating a capacitor of a semiconductor device, including the steps of: forming a bottom electrode coupled to an active area of a semiconductor substrate; performing an atomic layer deposition (ALD) technique to form a Ta₃N₅ dielectric layer with use of a gas precursor of TaCl₅ on the bottom electrode; and forming a top electrode on the Ta₃N₅ dielectric layer.

Also, a nitridation process is performed between the bottom electrode formation step and the Ta₃N₅ dielectric layer formation step to form a nitride layer on top portion of the bottom electrode. The nitration layer is formed to a thickness ranging from about 5 Å to 30 Å. In this case, the nitridation layer is operated with an in-situ or ex-situ process, including a plasma process, a rapid thermal process or a furnace process.

During the Ta₃N₅ dielectric layer formation, inert gase such as Ar or N₂ is used as a purge gas while NH₃ and TaCl₅ are used as a reactant gas and as a precursor gas, respectively. Also, a flow quantity of the reactant gas is controlled within a range from about 10 sccm to about 500 sccm. Ideally, a growth rate of the Ta₃N₅ dielectric layer is maintained within a range from about 0.1 Å to about 0.5 Å per cycle so for the Ta₃N₅ dielectric layer to have a thickness of approximately 150 Å.

In addition, the Ta₃N₅ dielectric layer is proceeded with oxidation process between the Ta₃N₅ dielectric layer formation step and the top electrode formation step. The oxidation process is performed with either a light wet oxidation or an in-situ or ex-situ process that utilizes a plasma process, a rapid thermal process or a furnace process.

The top electrode having a thickness ranging from about 100 Å to about 600 Å is formed with any of one film selected from TaN, TiN, W, WN, WSi, Ru, RuO₂, Ir, IrO₂ and Pt.

Lastly, an in-situ or ex-situ process is executed with use of HF vapor or HF solution for a surface treatment so that a native oxide, which is a residue remained on a surface of the bottom electrode, is removed prior to the dielectric layer formation.

### BRIEF DESCRIPTION OF THE DRAWING(s)

The above and other objects and features of the present invention will become apparent from the following description of the preferred embodiments given in conjunction with the accompanying drawings, in which:

FIG. 1A is a schematic diagram illustrating a deposition mechanism of chemical vapor deposition (CVD);

FIG. 1B is a schematic diagram illustrating a deposition mechanism of CVD;

FIG. 2A is a schematic diagram illustrating a deposition mechanism of atomic layer deposition (ALD);

FIG. 2B is a schematic diagram illustrating a deposition mechanism of ALD;

FIGS. 3A to 3C are cross-sectional views showing a process for forming a capacitor of a semiconductor device in accordance with a preferred embodiment of the present invention; and

FIG. 4 is a cross-sectional view of a capacitor in a semiconductor device in accordance with another preferred embodiment of the present invention.

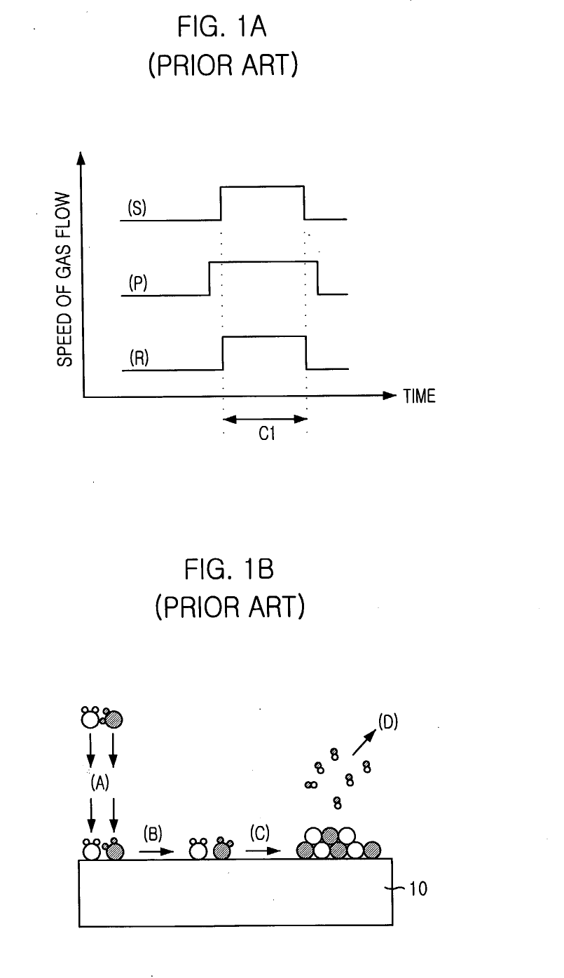

### DETAILED DESCRIPTION OF THE INVENTION

Other objects and aspects of the invention will become apparent from the following description of the embodiments with reference to the accompanying drawings, which is set forth hereinafter.

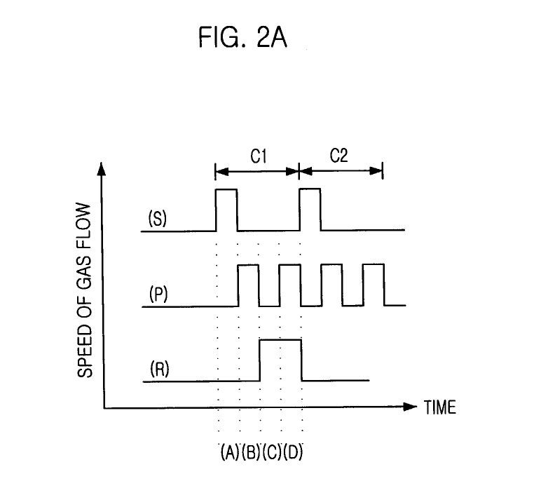

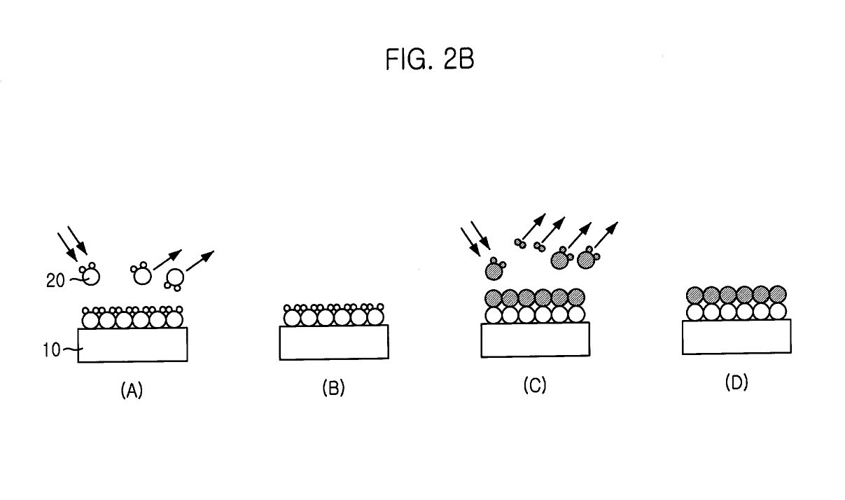

Referring to FIGS. 2A and 2B, there briefly described a mechanism of ALD for forming a Ta₃N₅ thin film in accordance with the present invention.

As shown in FIG. 2A, unlike to a chemical vapor deposition (CVD) process, in an ALD process a source gas (S), a purge gas (P) and a reactant gas (R) are alternately injected in that order during one cycle (C1). Thus, as illustrated in FIG. 2B, precursor gases required for a formation of a desired thin film are injected alternately in an orderly manner to a surface of a substrate 10. That is, at step (A), a precursor of the source gas 20 is injected in a saturation state to the surface of the substrate so to perform a chemical reaction and to deposit an atomic layer on the substrate. At step (B), the purge gas (P) removes residues of the source gas (S), and then, the reactant gas (R) react with the atomic layer in a saturation state to form a monolayer. With repeats of the above cycle at step (C) and (D), it is possible to form layers as with desired thicknesses, thereby easily varying the thickness. Also, since each gas reacts in a saturation state, the thin film formed by the ALD possesses superior uniformity in thickness and homogeneity, resulting in excellent step coverage even in three dimensions. Therefore, Teff is easily attainable for a high degree of electron property of a capacitor. Also, since residues such as carbon and so on are not formed, increases of leakage current and dielectric breakdown voltage can be prevented.

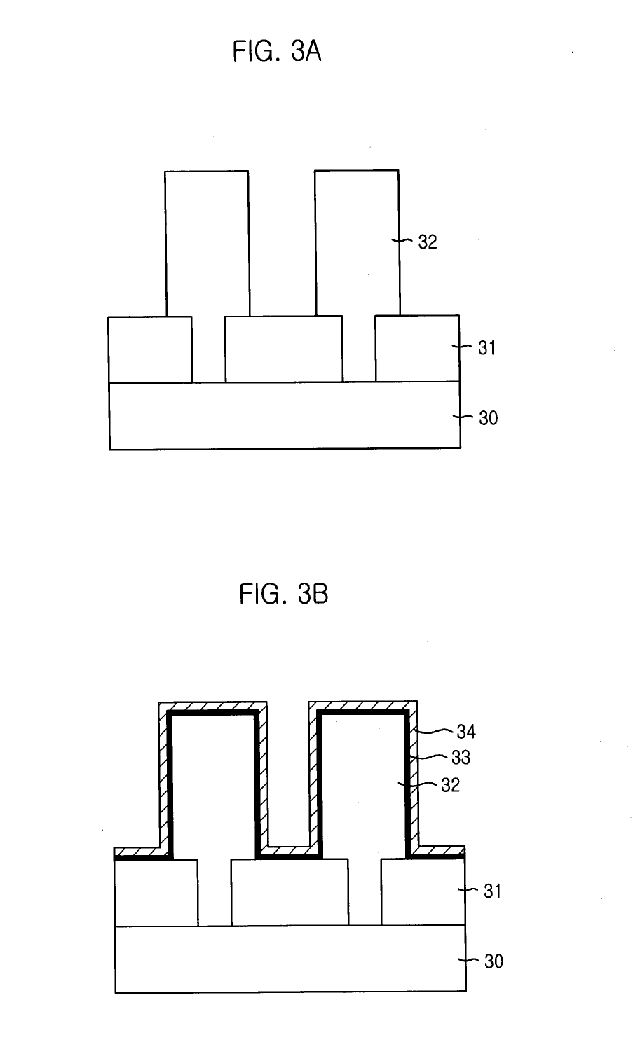

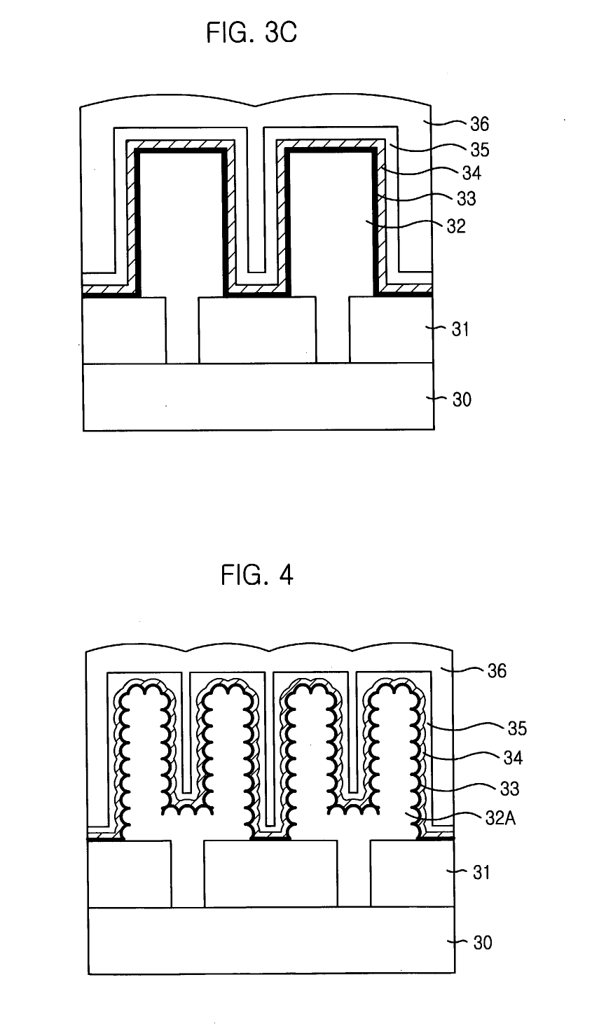

Next, referring FIGS. 3A to 3C, a method for forming a capacitor of a semiconductor device will be explained in accordance with a preferred embodiment of the present invention wherein an ALD process is applied.

With reference to FIG. 3A, an inter-layer insulating layer 31 is formed on a semiconductor substrate 30 made up of materials such as silicon, and then a contact hole for connecting a capacitor to the substrate 30 is formed by etching the inter-layer insulating layer 31 to expose an active area (not shown in the diagram) of the substrate 30. After this formation of the contact hole, a polysilicon layer is deposited by employing a low pressure chemical vapor deposition (LPCVD) and patterned to form a bottom electrode 32 of the capacitor. Here, the bottom electrode can be formed as one of stack, cylinder, fin, or stack cylinder forms, and in this embodiment, it is assumed that the bottom electrode is formed in the stack form. After this bottom electrode formation, in order to remove a native oxide residing on a surface of the bottom electrode 32, a surface treatment of the bottom electrode 32 is performed by using HF vapor or HF solution with an in-situ or ex-situ operation. At this time, an interfacial treatment is carried out with use of chemical solutions of NH₄OH or H₂SO₄ to wash an interface or to improve uniformity before/after the surface treatment using HF.

Referring to FIG. 3B, in order to prevent a formation of a low dielectric oxide layer, SiO₂, on the interface between the polysilicon layer of the bottom electrode 32 and a Ta₃N₅ dielectric layer during a deposition process and a subsequent thermal process for the Ta₃N₅ dielectric layer, nitridation process is performed to form a nitride layer 33 such as Si₃N₄ with a thickness ranging from about 5 Å to about 30 Å on a top surface of the bottom electrode 32. In this case, the nitridation process utilizes a plasma process including an in-situ or ex-situ operation, a rapid thermal process (RTP) or a furnace process. In case of the plasma process, the nitrification process is performed at a temperature ranging from about 300° C. to about 600° C. for about 30 seconds in a NH₃ or a N₂/H₂ gas ambient. When using the RTP, the nitridation process is performed at a temperature ranging from about 650° C. to about 950° C. with a NH₃ ambient. Also, in case of using the furnace process, the process is performed at a temperature ranging from about 500° C. to about 1000° C. with a NH₃ ambient.

As a next step, a dielectric layer 34 of the Ta₃N₅ thin film is formed to a thickness of approximately 150 Å by using TaCl₅ gas on the nitride layer 33. Referring to FIGS. 2A and 2B, there described in detail the formation of the dielectric layer 34 with the Ta₃N₅ thin film. Tacl₅ gas precursor, which is a source gas (S), is injected in a saturation state to a surface of the substrate during a first cycle (C1) to deposit chemically a Ta atomic layer at step (A). With use of Ar or N₂ as a purge gas (P), a residue of the source gas (S) is removed at step (B), and then, NH₃ as a reactant gas (R) in a saturation state and is reacted with Ta in the Ta atomic layer so as to form a single layer of the Ta₃N₅ thin film. The chemical reaction for the above is expected to be the reaction 1 as below.

<Reaction 1>

3TaCl₅(g)+5NH₃(g)→Ta₃N₅(s)+15HCl(g)

In this reaction, chemical vapor composed of Ta is provided with greater than 99.999% of TaCl₅ gas precursors with a constant quantity by using a flow controller such as mass flow controller (MFC) via evaporator retained to a temperature above 90° C. At this time, the evaporator including orifice, nozzle and solenoid valves as well as a supplier for a flow path of Ta vapor maintain a temperature to be in a range from about 90° C. to about 200° C. in order to prevent condensation of the Ta vapor. Through this method, a Ta₃N₅ thin film can be obtained with a thickness as desired by repeatedly depositing the chemically evaporated Ta and NH₃ gas precursors in a unit of atomic layer. In this case, the Ta is chemically evaporated and the NH₃ gas precursors are supplied to a chamber of which temperature is maintained between about 200° C. to about 500° C. in order to perform repetitive depositions. Also, at this time, TaCl₅ gas precursors and NH₃ reactant gas, of which flows are regulated in a surfacial saturation state within a range from about 10 sccm to about 500 sccm, are provided with a fixed quantity. Deposition rate, that is, growth rate of the Ta₃N₅ thin film is maintained within a range from about 0.1 Å to about 0.5 Å per cycle, and residue gases remained after the surface reaction of the Ta₃N₅ thin film are removed by a purge gas such as Ar, N₂, and other inert gases. As a result, there does not occur a gas phase reaction via reactant gas NH₃.

After forming the Ta₃N₅ dielectric layer 34 as described above, a predetermined number of oxidation processes are performed to improve a dielectric constant by correcting and crystallizing structural defects of the dielectric layer 34 such as micro crack or pin hole and non-uniformity. In this case, the oxidation process is operated with use of an in-situ or ex-situ operation, including a plasma process, a RTP or a furnace process. Ideally, in case of using the plasma process, temperature is maintained within a range from about 300° C. to about 600° C. in an ambient of N₂O or O₂, and in case of using the RTP, temperature is sustained in between about 600° C. and about 950° C. with an ambient of N₂O, O₂ or N₂ for about 30 seconds to about 10 minutes. In case of performing the furnace process, temperature is maintained within a range from about 600° C. to about 950° C. in an ambient of N₂O, O₂ or N₂ for about one minute to about 120 minutes. Also, the oxidation process can be alternatively performed as a light wet oxidation by fixing a quantity of a flow rate of O₂/H₂ gas less than about 3 in an ambient of O₂ and H₂ with the in-situ or ex-situ process.

As referred in FIG. 3c, a top electrode 35 is formed to completely fabricate a high capacity capacitor. Ideally, the top electrode 35 is formed with a thickness of about 100 Å to about 600 Å in a single layer selected from TaN, TiN, W, WN, WSi, Ru, RuO₂, Ir, IrO₂ and Pt. Then, during a subsequent thermal process, a doped polysilicon layer is formed on a whole surface of a substrate. Herein, the doped polysilicon layer enacts as a buffer layer 36 in order to prevent degradation of the capacitor.

FIG. 4 is a cross-sectional view showing a capacitor of a semiconductor device having a Ta₃N₅ thin film fabricated in accordance with another embodiment of the present embodiment. In this embodiment, a bottom electrode 32A is formed with a structure of hemispherical convexo-concave. A Ta₃N₅ dielectric layer 34 is formed on top of the bottom electrode 32A through the identical procedures as described in the above embodiment.

According to the present invention, it is possible to augment a capacitor capacity in a higher degree by forming a Ta₃N₅ thin film with a high dielectric constant greater than 100 for a dielectric layer of the capacitor. Also, since the Ta₃N₅ thin film is formed with an ALD method, it is possible to prevent carbon radicals from remaining and to obtain excellent step coverage. Therefore, the leakage current via dielectric layer and the degradation of dielectric breakdown voltage characteristic can be prevented, and the effective thickness of the dielectric layer can be easily secured.

While the present invention has been shown and described with respect to the particular embodiments, it will be apparent to those skilled in the art that many changes and modifications may be made without departing from the sprit and scope of the invention as defined in the appended claims.

What is claimed is:

1. A method for forming a capacitor of a semiconductor device, comprising the steps of:
forming a bottom electrode coupled to an active area of a semiconductor substrate;
performing an atomic layer deposition (ALD) technique to form a Ta₃N₅ dielectric layer with use of a gas precursor of TaCl₅ on the bottom electrode; and
forming a top electrode on the Ta₃N₅ dielectric layer.

2. The method as recited in claim 1, further comprising the step of forming a nitride layer on the bottom electrode by performing a nitridation process, after forming the bottom electrode.

3. The method as recited in claim 2, wherein the nitride layer is formed having a thickness ranging from about 5 Å to about 30 Å.

4. The method as recited in claim 2, wherein the nitridation process is performed through a plasma process, a rapid thermal process or a furnace process.

5. The method as recited in claim 4, wherein the plasma process is performed at a temperature ranging from about 300° C. to about 600° C. in an ambient of NH₃ or N₂/H₂ for about 30 seconds to about 5 minutes.

6. The method as recited in claim 4, wherein the rapid thermal process is performed at a temperature ranging from about 650° C. to about 950° C. in a NH₃ ambient.

7. The method as recited in claim 4, wherein the furnace process is performed at a temperature ranging from about 500° C. to about 1000° C. in a NH₃ ambient.

8. The method as recited in claim 1, wherein the Ta₃N₅ dielectric layer is formed with use of a reactant gas NH₃.

9. The method as recited in claim 8, wherein the TaCl₅ gas precursors and the reactant gas are controlled to maintain their flow quantities within a range between about 10 sccm to about 500 sccm.

10. The method as recited in claim 9, wherein the Ta₃N₅ dielectric layer is formed with a growth rate ranging from about 0.1 Å to about 0.5 Å per cycle.

11. The method as recited in claim 1, further comprising the step of oxidating the Ta₃N₅ dielectric layer, after forming the Ta₃N₅ dielectric layer.

12. The method as recited in claim 11, the oxidation process is performed with use of any one of a plasma process, a rapid thermal process or a furnace process.

13. The method as recited in claim 12, wherein the plasma process is performed at a temperature within a range from about 300° C. to about 600° C. in an ambient of N₂O or O₂.

14. The method as recited in claim 12, wherein the rapid thermal process is performed at a temperature within a range from about 600° C. to about 950° C. in an ambient of any of one selected gas from a group of N₂O, O₂ and N₂ for 30 seconds to 10 minutes.

15. The method as recited in claim 12, the furnace process is performed at a temperature within a range from about 600° C. to about 950° C. in an ambient of any of one selected gas from a group consisting of N₂O, O₂ and N₂ for about one minute to about 120 minutes.

16. The method as recited in claim 11, wherein the oxidation process is executed with a light wet oxidation operation in an ambient of O₂/H₂ by fixing a quantity of O₂/H₂ gas flow ratio to be less than about 3.

17. The method as recited in claim 1, wherein the top electrode is made of any of one selected from a group consisting of TaN, TiN, W, WN, WSi, Ru, RuO₂, Ir, IrO₂, and Pt.

18. The method as recited in claim 1, wherein the top electrode has a thickness ranging from about 100 Å to about 600 Å.

19. The method as recited in claim 1, further comprising the step of forming a buffer layer with a doped polysilicon layer on the top electrode, after forming the top electrode.

20. The method as recited in claim 1, wherein the Ta₃N₅ dielectric layer is formed on the bottom electrode of which a surface is processed with HF and a native oxide layer on the surface is removed.
